(19) United States
(12) Patent Application Publication
(10) Pub. No.: US 2024/0074336 A1
(43) Pub. Date: Feb. 29, 2024

(54) SELF-ALIGNED PATTERNED PROJECTION LINER FOR SIDEWALL ELECTRODE PCM

(71) Applicant: International Business Machines Corporation, Armonk, NY (US)

(72) Inventors: Injo Ok, Loudonville, NY (US); Timothy Mathew Philip, Albany, NY (US); Jin Ping Han, Yorktown Heights, NY (US); Ching-Tzu Chen, Ossining, NY (US); Kevin W. Brew, Niskayuna, NY (US); Lili Cheng, Rexford, NY (US)

(21) Appl. No.: 17/894,549

(22) Filed: Aug. 24, 2022

(51) Int. Cl. H01L 45/00

(52) U.S. Cl. CPC H01L 45/126; H01L 45/06; H01L 45/1233; H01L 45/1675

(57) ABSTRACT

A memory device and method of forming a projection liner under a mushroom phase change memory device with sidewall electrode process scheme to provide self-aligned patterning of resistive projection liner during sidewall electrode formation.

### BACKGROUND

The present disclosure relates in general to semiconductor devices and methods of manufacturing semiconductor devices and, in particular, phase change memory devices with a resistive projection liner.

Phase change materials can change phase between an amorphous state and a crystalline state by application of specific levels of electrical current or voltage. The amorphous state can be characterized by a relatively higher electrical resistivity than the crystalline state, causing different levels of voltages or current being used for setting the phase of the phase change material. A phase change memory (PCM) element can use phase change material to increase memory capacity. In an aspect, the different voltage or current levels being applied to change phase among an off state (e.g., no voltage or current applied), the amorphous state, the crystalline state, and different types of the crystalline state, can cause the phase change memory to represent more than two values (e.g., binary) of data that can be stored in a phase change memory element.

Utilizing phase change memory for analog computing requires memory cells with resistance that changes linearly with program pulses and is predictable and repeatable.

Amorphous phase change materials often suffer from resistance drift, whereby the resistance of the cell changes over time, which makes the resistance of the cell unpredictable.

To mitigate resistance drift, a projection segment, a parallel resistor that bypasses current around the amorphous volume, is added to the cell.

Depending on the geometry of the cell and projection segment, however, the cell resistance can become very non-linear. For conventional “mushroom” PCM cell designs, the simulated resistance of the cell with a small (e.g., 2 nm) projection segment that covers the bottom of the phase change material (GST) is highly non-linear with the side length of the amorphous volume.

### SUMMARY

In one embodiment, a semiconductor structure is generally described. The semiconductor structure is a resistive projection liner formed under a memory device. The memory device can be a mushroom PCM device.

Further to this embodiment, the projection liner under a PCM device is formed during sidewall electrode process scheme to provide a self-aligned patterning of the resistive projection liner during sidewall electrode formation.

There is provided a structure and method of forming projection liner under a mushroom PCM device with sidewall electrode process scheme to provide self-aligned patterning of resistive projection liner during sidewall electrode formation.

In one embodiment, there is provided a memory device. The memory device comprises: a bottom metal electrode having a top surface; a memory cell disposed above the bottom electrode, the memory cell having a bottom layer comprising a phase change material; a resistive projection liner element connecting to the bottom layer of the memory cell; and a metal heater element connecting the top surface of the bottom electrode to the resistive projection liner element.

The resistive projection liner element being self-aligned to the metal heater element enables a reduction of an area of contact to the memory cell.

In a further embodiment, there is provided a memory device. The memory device according to the further embodiment comprises: a bottom metal electrode having a top surface; a memory cell disposed above the bottom electrode, the memory cell having a bottom layer comprising a phase change material; a metal heater element connecting the top surface of the bottom electrode to a bottom surface of the bottom layer of the memory cell, the metal heater element having a substantially vertical extending sidewall liner portion and a horizontal liner portion extending to an edge of the bottom layer.

The horizontal liner portion extending for a length less than an entire length of the bottom layer of the memory cell reduces an area of contact to the memory cell.

A method for fabricating a memory device is generally described. The method can include: depositing, on a semiconductor structure having one or more formed bottom metal electrodes, one or more first heater dielectric material layer structures, each first heater dielectric material structure having a sidewall edge extending in a first orientation and in alignment with a surface of each of the one or more formed bottom metal electrodes; forming a metal heater layer having a portion extending vertically along the sidewall edge of each the deposited first (heater) dielectric material structure and a bottom portion electrically connecting to the surface each the one or more formed bottom metal electrodes; depositing a further dielectric material layer to fill openings at a surface of the semiconductor structure defined between sidewall edges of the one or more first heater dielectric material layer structures and planarizing a top surface thereof; depositing a projection liner layer on the planarized top surface; forming a pattern of vertically extending spacer material structures on the projection liner layer, each the formed vertically extending spacer material structure extending in a second orientation transverse to the first orientation and overlapping the vertically extending over the sidewall portion of the metal heater layer; and transferring a pattern defined by the vertically extending spacer material layers to the surface of each of a plurality of one or more formed bottom electrodes by etching the projection liner layer and metal heater layer to self-align a width of a remaining projection liner layer portion to a width of the cut vertically extending sidewall metal heater layer portion in the second orientation above each bottom electrode.

The method provides for a resistive projection liner element being self-aligned to the metal heater element to enable a reduction of an area of contact to the PCM memory cell.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1A depicts a cross sectional view of an exemplary structure that can be used for forming a self-aligned projection liner for a phase change memory cell in one embodiment.

FIG. 1B depicts a cross sectional view of the resulting structure of FIG. 1A after depositing a metal liner and spacer dielectric layers;

FIG. 1C depicts a cross sectional view of the resulting structure of FIG. 1B after etching back part of spacer and metal liner layers;

FIG. 1D depicts a cross sectional view of the resulting structure of FIG. 1C after depositing a further protective dielectric cap and dielectric material fill and performing a top CMP;

FIG. 1E depicts a top-down layout view of the resulting structure corresponding to structures of FIGS. 1E-1 and 1E-2 used for forming a self-aligned projection liner for a phase change memory cell;

FIG. 1E-1 depicts a cross sectional view of a resulting structure taken along an X-X cross-section of the formed structure of FIG. 1D after depositing a thin projection liner layer and transverse oriented mandrel structure, and FIG. 1E-2 shows a view taken along a Y-Y cross-section of the formed structure of FIG. 1E-1;

FIG. 1F-1 depicts a cross sectional view of a resulting structure taken along an X-X cross-section of the formed structure of FIG. 1E-1 after depositing a dielectric spacer material layer, and FIG. 1F-2 shows a view taken along a Y-Y cross-section of the formed structure of FIG. 1F-1;

FIG. 1G-1 depicts a cross sectional view of a resulting structure taken along an X-X cross-section of the formed structure of FIG. 1F-1 after etching back portions of the dielectric spacer material layer, and FIG. 1G-2 shows a view taken along a Y-Y cross-section of the formed structure of FIG. 1G-1;

FIG. 1H-1 depicts a cross sectional view of a resulting structure taken along an X-X cross-section of the formed structure of FIG. 1G-1 after removing the transverse oriented mandrel structure, and FIG. 1H-2 shows a view taken along a Y-Y cross-section of the formed structure of FIG. 1H-1;

FIG. 1I-1 depicts a cross sectional view of a resulting structure taken along an X-X cross-section of the formed structure of FIG. 1H-1 after pattern transfer to form self-aligned projection liner, and FIG. 1I-2 shows a view taken along a Y-Y cross-section of the formed structure of FIG. 1I-1;

FIG. 1J-1 depicts a cross sectional view of a resulting structure taken along an X-X cross-section of the formed structure of FIG. 1I-1 after depositing a further dielectric fill material, and FIG. 1J-2 shows a view taken along a Y-Y cross-section of the formed structure of FIG. 1J-1;

FIG. 1K-1 depicts a cross sectional view of a resulting structure taken along an X-X cross-section of the formed structure of FIG. 1J-1 after depositing material layers for forming a PCM cell, and FIG. 1K-2 shows a view taken along a Y-Y cross-section of the formed structure of FIG. 1K-1;

FIG. 1L-1 depicts a cross sectional view of a resulting structure taken along an X-X cross-section of the formed structure of FIG. 1L-1 after PCM cell patterning and etching, and FIG. 1L-2 shows a view taken along a Y-Y cross-section of the formed structure of FIG. 1L-1;

FIG. 1M-1 depicts a cross sectional view of a resulting structure taken along an X-X cross-section of the formed structure of FIG. 1L-1 after forming top electrode connections to PCM cell, and FIG. 1M-2 shows a view taken along a Y-Y cross-section of the formed structure of FIG. 1M-1;

FIG. 2 depicts a three-dimensional view of the resulting PCM cell having self-aligned projection liner according to a first embodiment;

FIG. 3A depicts a view of the resulting PCM cell having self-aligned projection liner extending along the length of the PCM cell, and FIG. 3B depicts a view of the resulting PCM cell having self-aligned projection liner extending less than the length of the PCM cell;

FIGS. 4A-4M illustrate three-dimensional cross-sectional views depicting a sequence of semiconductor manufacturing steps for a PCM cell that includes a self-aligned heater metal liner integration scheme that results in semiconductor PCM structures having self-aligned sidewall metal heater and top metal heater portions according to a second embodiment.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following descriptions, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Conventionally, to mitigate resistance drift in resistive memory cells such as PCM cells, a parallel resistor that bypasses current around the amorphous volume, is added to the cell.

Depending on the geometry of the PCM cell and a projection segment, the PCM cell resistance can become very non-linear.

The present disclosure provides a projection liner integration scheme for a sidewall electrode PCM cell. In embodiments, a patterned projection liner is formed where the width of the projection liner is etched at the same time as the heater is etched, forming a self-aligned projection liner.

For a mushroom PCM cell design, the present disclosure provides a projection liner integration scheme in which a projection liner can be self-aligned with the formation of the cell, i.e., projection liner can be significantly narrower than with the non-self-aligned case, which can result in higher dynamic range. As liner typically drops dynamic range significantly, the self-aligned projection liner enables larger switching window with drift mitigation. Low drift plus large switching window is a key enabler for analog artificial intelligence (AI) applications.

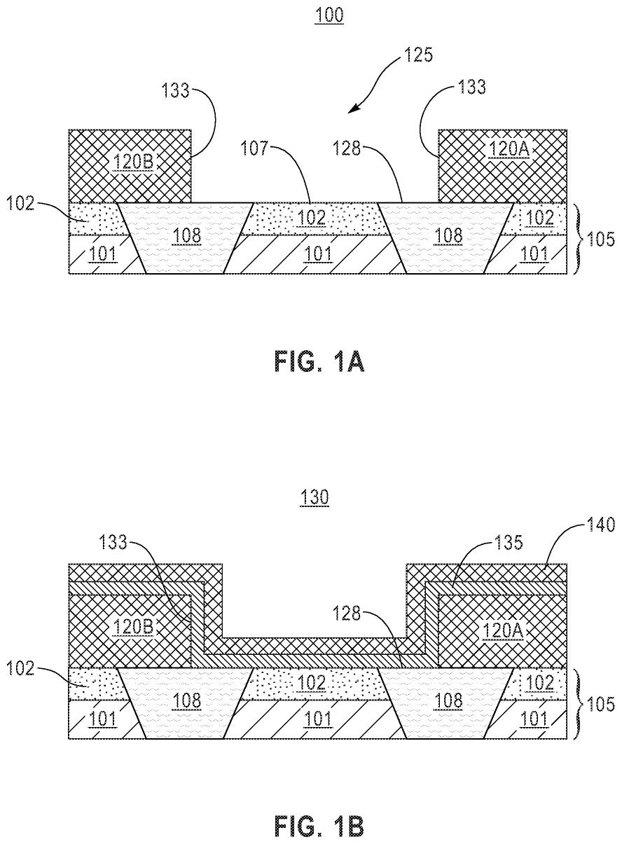

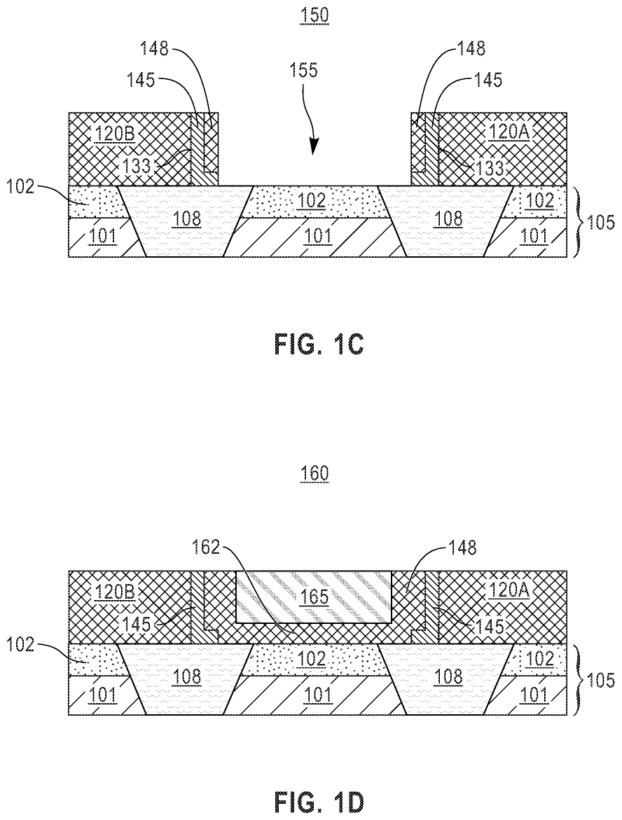

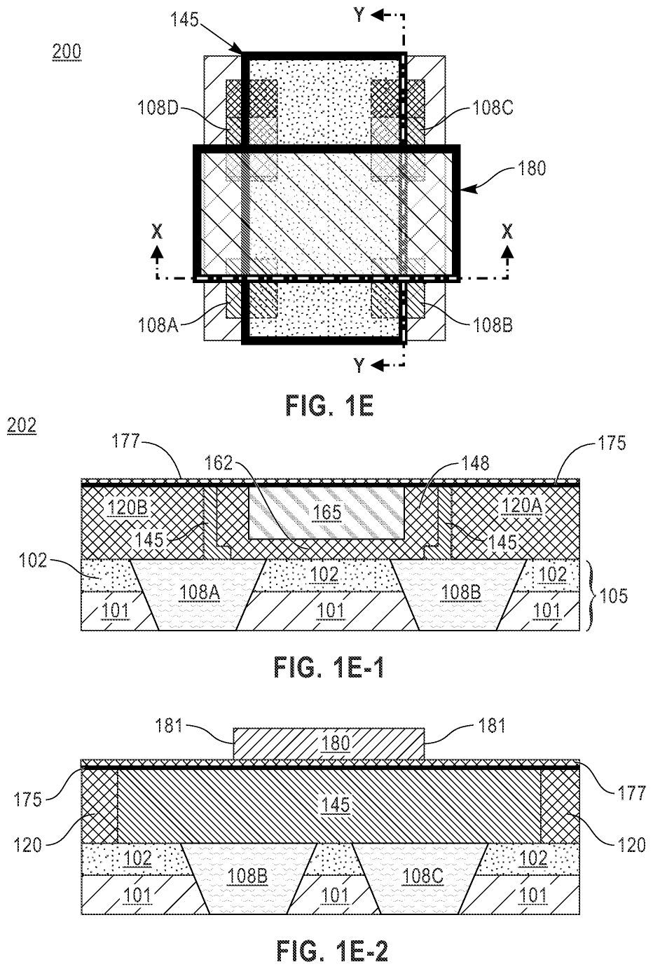

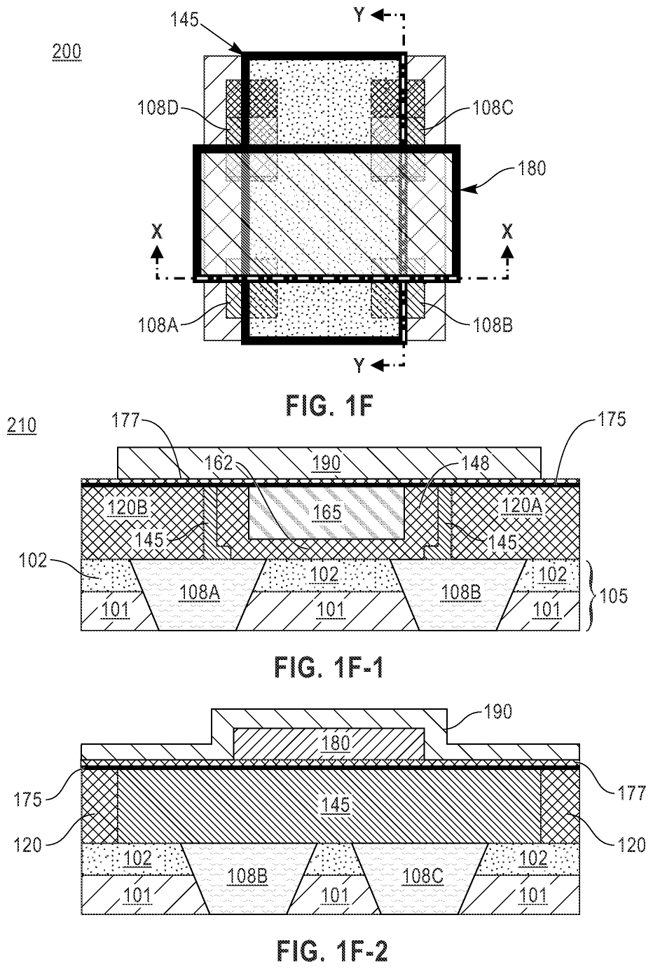

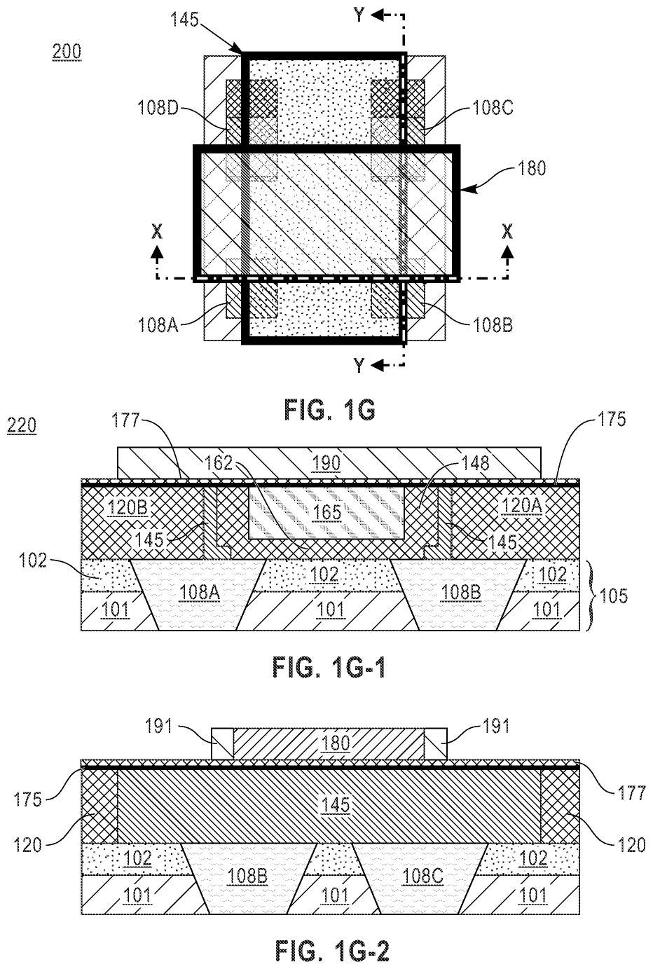

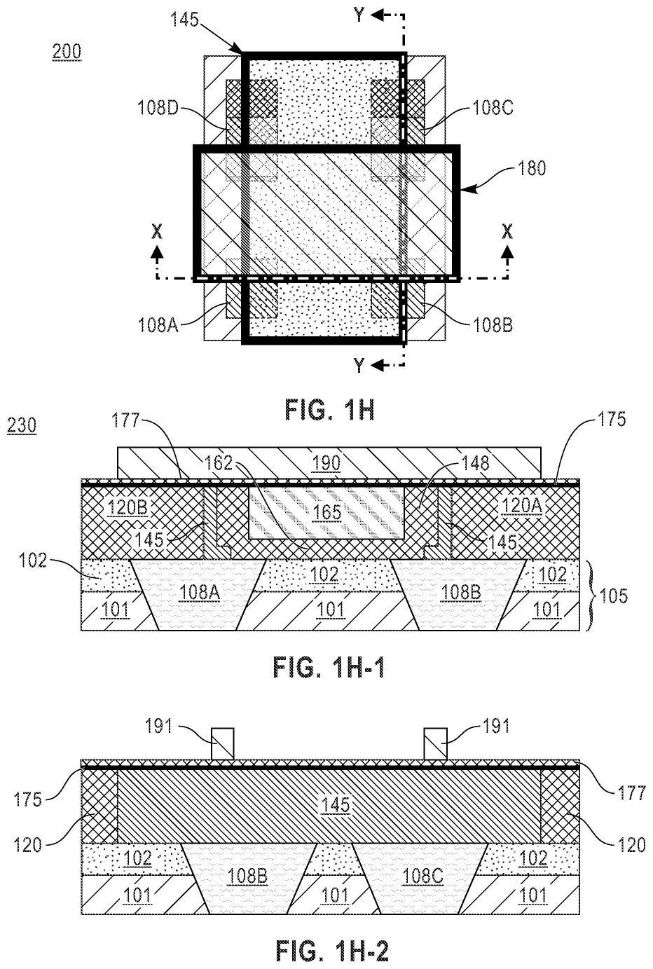

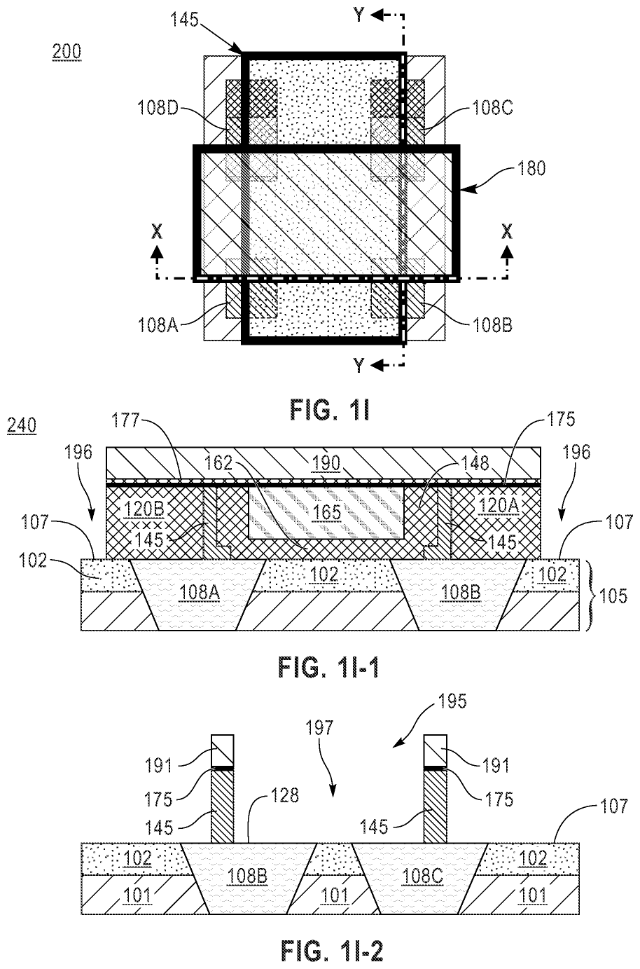

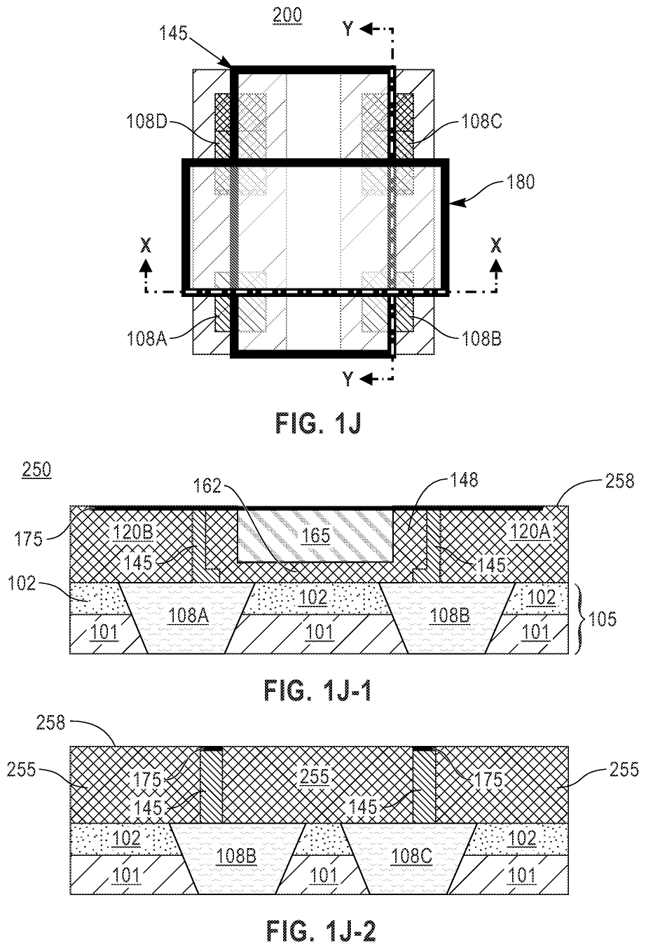

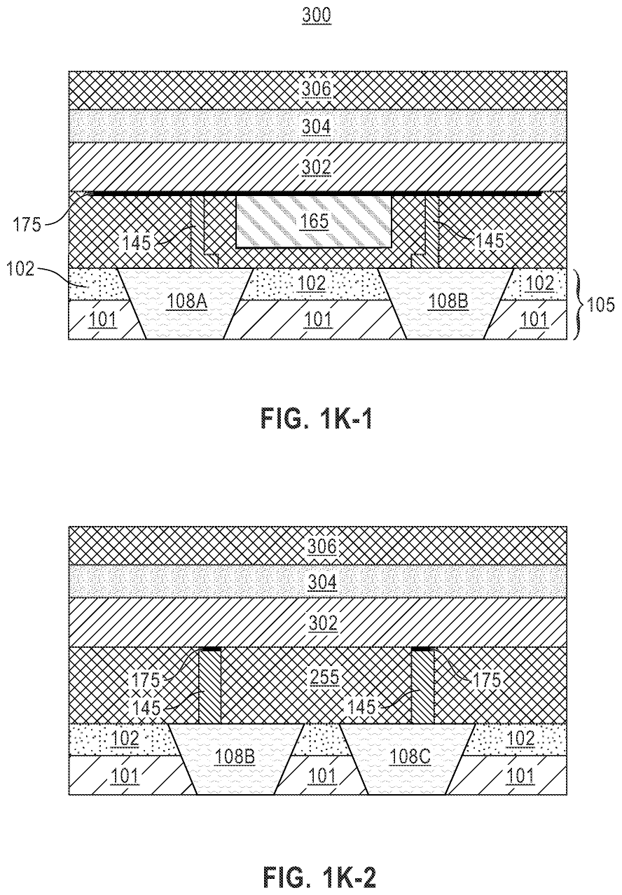

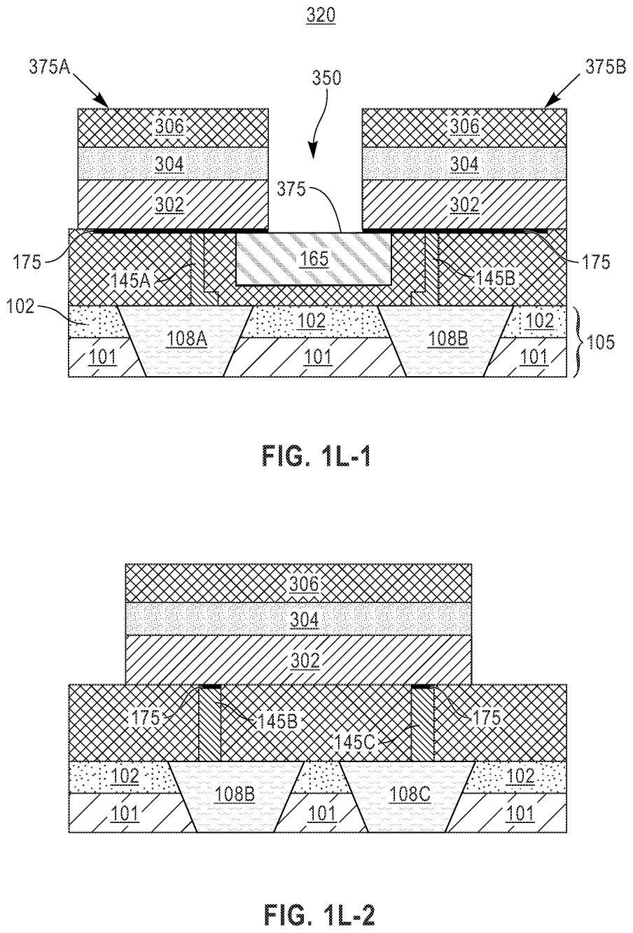

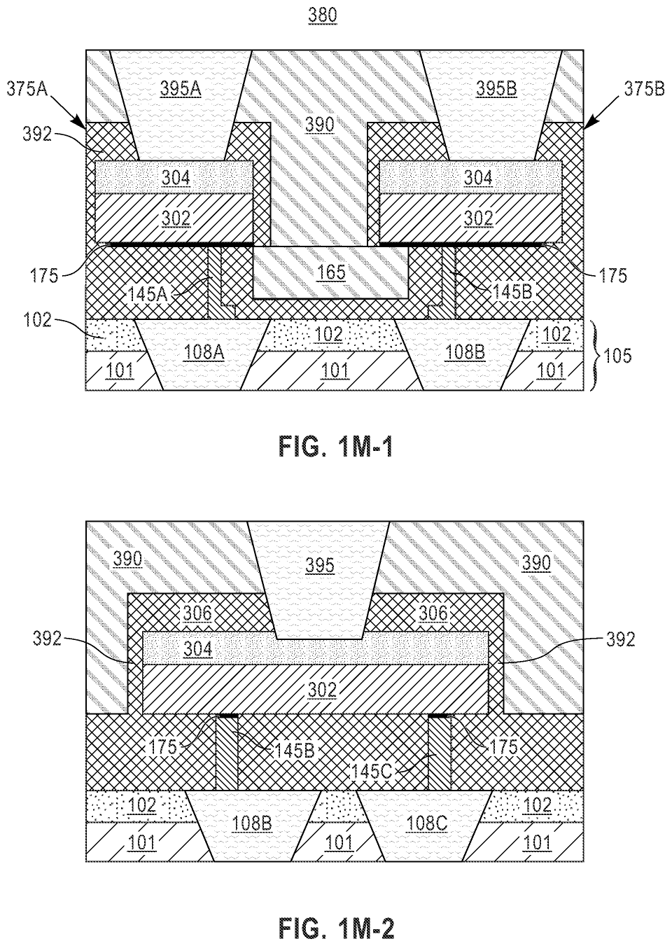

FIG. 1A to FIG. 1M1-2 illustrate cross-sectional views depicting a sequence of semiconductor manufacturing MOL and BEOL process steps of a self-aligned projection liner integration scheme that results in semiconductor PCM structures that include an added self-aligned projection liner according to a first embodiment. In this embodiment, the formation of the projection liner is formed during formation of the PCM cell without use of separate mask set and obviates need for patterning and etching of the projection liner separate from PCM processing.

FIG. 1A is a cross sectional view of an exemplary structure 100 that can be used as the basis for forming a PCM cell structure using a self-aligned projection liner integration scheme in one embodiment. Initial structure 100 is formed of MOL or BEOL semiconductor manufacturing processes for fabricating conductive wiring, contacts, insulating material layers, metal levels, etc. that can interconnect already formed individual devices such as transistors, capacitors, resistors, etc. (not shown). The starting structure 100 can include a stack of one or more dielectric layers 105 including, from bottom to top, dielectric layers including a first dielectric layer 101, e.g., SiN, SiON, SiOCN as like materials, and a second interlevel dielectric level layer or dielectric cap layer 102. The second insulator layer 102 can be composed of dielectric materials, such as silicon dioxide, silicon nitride, silicon carbide nitride, or other types of low-k dielectric materials. The term “low-k” as used throughout the present application denotes a dielectric material that has a dielectric constant of less than 4.0; all dielectric constants are measured under vacuum (unless otherwise stated herein). In an embodiment, interlevel dielectric layer 102 can be tetraethoxysilane (TEOS) or ifliornated tetraethyl orthosilicate (FTEOS) material or other materials such as SiOCH or SiOC. Such a dielectric film can be deposited using plasma enhanced physical vapor deposition (PECVD).

Formed within dielectric layer stack 105 are a plurality of bottom electrodes 108 for eventual connection to a PCM cell, each bottom electrode 108 having a surface 128 co-planar with a top surface 107 of an interlevel dielectric layer 102. The metal bottom electrodes 108 can be composed of metal such as graphite, copper, tungsten, Pt, Ru, Ni, or other metal or metal alloy suitable for forming an electrode that connects to the other conductors/devices (not shown). The bottom electrode metal material structures 108 can be formed by photolithographic patterning, etching and deposition processes including, but not limited to, atomic layer deposition (ALD), chemical vapor deposition (CVD), or physical vapor deposition (PVD) processes.

FIG. 1A further shows the result of material deposition, photolithographic mask patterning and etching processes to form respective dielectric heater structures 120A, 120B on top of the surface 107 that cover a portion of a respective bottom electrode surface 128. In a non-limiting embodiment shown in FIG. 1A, each dielectric heater structure 120A overlaps with and covers approximately one-half a surface of a respective electrode top surface 128 and leaves approximately one-half of the surface 128 of each bottom electrode 108 exposed. In one embodiment, the structure 100 in FIG. 1A results from a deposition of a dielectric heater material layer (not shown) and, using photolithographic mask patterning processes and plasma-etching, dry-etching or ion beam etching or laser ablation processes to result in the forming of an opening 125 so that remaining dielectric heater layer portions 120A, 120B cover a portion of each bottom electrode surface 128 on top the layer stack 105. In an embodiment, a reactive-ion etching (RIE) is used to form the opening resulting in the formed dielectric heater layer portions 120A, 120B each portion having inner sidewalls 133. The deposited dielectric heater layer portions 120A, 120B can be composed of dielectric materials, such as silicon nitride (SiN), silicon carbide nitride, or other types of dielectric heater materials, e.g., high-k dielectric such as Al₂O₃, HfO₂, La₂O₃, AlN.

FIG. 1B is a cross sectional view of a resulting structure 130 of FIG. 1A formed after a further deposition of a heater metal layer 135 and an overlying protective spacer layer 140. As shown, a side wall electrode process is applied to first deposit the heater metal 135 to cover the top surface of the deposited dielectric heater layer portions 120A, 120B, the heater metal 135 conforming to the inner sidewalls 133 and covering the top surface 107 of the exposed ILD layer 102 including a portion extending over and electrically connected to each of the remaining exposed surfaces of each bottom electrode. The heater metal layer 135 can be deposited to thickness ranging between 6 nm-8 nm however heater metal layer thickness can range from between 2 nm-10 nm. The deposited protective spacer material layer 140 overlies heater metal layer 135 and is deposited to a thickness ranging anywhere from between 10 nm-30 nm. Both layers 135, 140 can be deposited by, but not limited to, atomic layer deposition (ALD), chemical vapor deposition (CVD), or physical vapor deposition (PVD) processes. Metal heater materials can include, but are not limited to: W, Ti, TiN, or other liner metals or metal nitrides such as TaN, Ru, WOx, TeAsGeSiSe-based OTS. The protective space material can include but is not limited to an oxide or nitride insulator, such as silicon oxide, silicon nitride, or silicon-oxynitride, etc. . . . . Example protective spacer materials can include SiN, AlN, Al₂O₃.

FIG. 1C is a cross sectional view of the resulting structure 155 of FIG. 1B formed after undergoing an RIE or plasma-etching process to etch back portions of the spacer material layer 140 and etch back portions of the heater metal material layer 135 in the structure 130 of FIG. 1B. FIG. 1C depicts the remaining etched back spacer material layer portions 148 and the remaining etched back heater metal material portions 145 located along the sidewall edges 133 of the dielectric heater layer portions 120A, 120B. The heater is etched back a distance that ensures that a bottom portion of the heater metal material portion 145 is completely contacting the underlying electrode 108 and does not exceed an edge of the underlying electrode 108. As a result of the etching, an opening 155 is formed to expose the surface of the interlevel dielectric layer 102.

FIG. 1D is a cross sectional view of a resulting structure 160 of FIG. 1C formed after depositing a protective cap layer 162 and fill in dielectric material 165 within the opening 155 of the structure 150 of FIG. 1C. The protective cap layer 162 can be of a dielectric material such as a nitride dielectric which consists of Si, C, H, and N, e.g., SiN, SiCHN, or combinations thereof and can be deposited by atomic layer deposition, chemical vapor deposition, or physical vapor deposition processes. The fill-in dielectric material layer 165 can include a Tetraethyl orthosilicate (TEOS) dielectric material layer 165 using CVD, PECVD or PVD processes. Afterwards, the structure can undergo chemical mechanical polishing (CMP) processes to planarize a top surface of the-structure 160 of FIG. 1D and to tailor a height of the heater metal layer 145 to a desired heater electrode height. In an embodiment, the heater metal structure 145 can be of a height ranging from between 20 nm-200 nm.

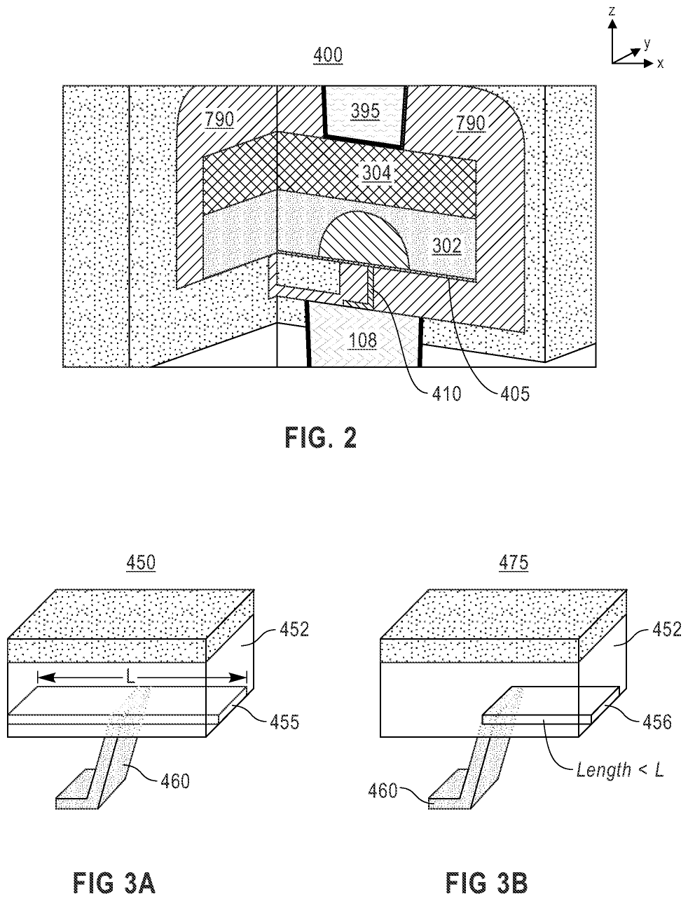

FIG. 1E shows a top-down layout view of a portion of the several physical intermediate PCM cell structures 200 including formed interlevel dielectric stack and bottom electrodes. The top-down layout view of FIG. 1E show the intermediate structures for forming several PCM cells 200 that include bottom electrodes 108A, 108B, 108C and 108D resulting from earlier MOL and BEOL processing steps (not shown). The intermediate PCM cell structures 200 shown results from the processing steps up to and including steps performed that result in structures shown in FIGS. 1E-1 and 1E-2 used for forming a self-aligned projection liner for a phase change memory cell.

In particular, FIG. 1E-1 depicts a cross sectional view of a resulting structure taken along an X-X cross-section of the formed structure of FIG. 1D after depositing a thin projection liner layer, a protective dielectric cap layer, and transverse oriented mandrel structure. In particular, FIG. 1E-1 shows a resulting structure 202 formed after further depositing a projection liner material layer 175 on the top surface of the structure 160 of FIG. 1D. That is, after applying the CMP process to tailor the height of the heater metal material portions 145, a projection liner layer 175 of liner material is deposited using CVD, PVD, or ALD processes. In one embodiment, the projection liner layer 175 can be deposited to a thickness ranging from between 1 nm-10 nm. As further shown, on top the projection liner layer 175 is further deposited a protective dielectric cap layer 177 of a thickness ranging from between 10 nm-100 nm. The projection liner layer 173 can be any type of metal nitride liners or metallic liner material. The protective dielectric cap layer 175 can be any dielectric material, e.g. SiN.

FIG. 1E-2 shows a view taken along a Y-Y cross-section of the formed intermediate PCM cell structure 202 depicted in FIG. 1E-1. In particular, FIG. 1E-2 is a cross sectional view of the resulting structure formed after further mask patterning and subsequent depositing of projection liner layer 175, protective dielectric cap layer 177, and a mandrel material structure 180 using CVD, PVD, or ALD processes. In an embodiment, the top surface of the dielectric cap layer 177 of the structure 202 is patterned with a mask and a mandrel material is deposited and the mask removed to form a mandrel structure 180 oriented in a direction transverse to the orientation of the heater metal layer 145 on the top surface of the structure 160 of FIG. 1D between two adjacent electrodes along the Y-Y direction (e.g., bottom electrodes 108B, 108C). The use of conventional semiconductor photolithographic masking and etching techniques result in a mandrel material structure 180 of a width defining two edges 181, each edge 181 overlapping a respective adjacent bottom electrode, e.g., electrodes 108B, 108C. Deposited mandrel material structure 180 can be of an amorphous silicon (a-Si) material Other types of mandrel materials can include, but are not limited to BARC (bottom anti-reflection coating), OPL (outer plexiform layer), SiO₂, SiOC, AlN, Al₂O₃, TiN, TaN.

FIG. 1F-1 shows a further view taken along an X-X cross-section of the formed intermediate PCM cell structure 200 of the layout depicted in FIG. 1E, the further view showing a resulting structure 210 formed after further depositing a spacer material layer 190 on the exposed sidewall surfaces and top surface of the structures 202 of FIGS. 1E-1, 1E-2. That is, after depositing mandrel layer 180, deposition processes are performed to deposit a spacer material layer 190 on the remaining exposed surfaces.

FIG. 1F-2 shows a view taken along a Y-Y cross-section of the formed intermediate PCM cell structure 200 of the layout depicted in FIG. 1E after further depositing a spacer material layer 190 on all the exposed top surfaces of the structures 202 of FIGS. 1E-1, 1E-2. Spacer material layer 190 can be of a material such as AlN, Ti₂O₃, SiN, TiN, SiO₂, SiOC, Al₂O₃. As shown in FIG. 1F-2, the spacer material layer 190 completely covers the exposed sidewall surfaces and top surface of mandrel 180 and cap layer 177 on top of metal heater structures and dielectric heater material layer 120 adjacent each side of the heater metal 145.

FIG. 1G-1 shows a further view taken along an X-X cross-section of the formed intermediate PCM cell structure 200 corresponding to the layout depicted in FIG. 1E, the further view showing a resulting structure 220 formed after further processes to pattern and etch-back the deposited spacer material layer 190. That is, after depositing the spacer material layer 190 that completely covers the exposed surfaces of mandrel 180 and cap layer 177, a dry or RIE etch process is performed to remove those portions of the spacer material layer 190 above the mandrel structure 190 while leaving thin sidewall spacer portions 191 on each side of the mandrel material layer 180.

FIG. 1G-2 shows a view taken along a Y-Y cross-section of the formed structure of FIG. 1G-1 after the etching back of the deposited spacer material layer 190. Spacer material layer 190 can be etched back to remove all spacer material on top of mandrel structure 190 while leaving thin sidewall spacer portions 191 on either side of the mandrel material layer 180. Each respective thin sidewall spacer portion 191 are in vertical alignment with a respective bottom electrode, e.g., electrodes 108B, 108C, as shown in FIG. 1G-2.

FIG. 1H-1 shows a further view taken along an X-X cross-section of the formed intermediate PCM cell structure 200 of the layout depicted in FIG. 1E, the further view showing a resulting structure 230 formed after further processes to remove (pull) the mandrel. That is, mask patterning and dry-etching (e.g., RIE) or plasma-etching processes are performed to remove the mandrel structure 180 from the surface of cap layer 177 between sidewall spacers 191. The sidewall spacers 191 remain.

FIG. 1H-2 shows a view taken along a Y-Y cross-section of the formed structure of FIG. 1H-1 after pulling the mandrel structure 180. As seen in FIG. 1H-2, the etching removes the mandrel structure while leaving the formed sidewall spacers 191 in alignment with respective surfaces of respective bottom electrodes, e.g., electrodes 108B, 108C.

FIG. 1I-1 shows a further view taken along an X-X cross-section of the formed intermediate PCM cell structure 200 of the layout depicted in FIG. 1E, the further view showing a resulting structure 240 formed after further processes to transfer the spacer pattern defined by spacers 191 by etching the structure to cut the heater structure 145. That is, mask patterning and dry- or plasma-etching processes are performed to remove those portions of the cap layer 177, projection liner 175, heater metal structure 145 in a pattern defined by the spacers 191.

FIG. 1I-2 shows a view taken along a Y-Y cross-section of the formed structure of FIG. 1I-1 after transferring the spacer pattern 195 defined by spacers 191 by etching the structure to cut the heater structure 145. As seen in FIG. 1I-2, a dry- or plasma-etch (e.g., RIE) process removes the portions of the heater structure in a manner that self-aligns the respective heater with the respective sidewall spacer 191 and in further alignment with a respective bottom electrode, e.g., electrodes 108B, 108C. That is, the patterned projection liner is formed where the width of the projection liner 175 is etched at the same time as the heater metal 145 is etched, forming a self-aligned projection liner.

In particular, FIG. 1I-1 and I1-2 depict the result of further applied lithographic patterning and RIE etching steps for transferring the pattern formed by sidewall spacers 191, the etching forming cuts 196 at either side of the dielectric heater 120A, 120B stopping on the surface of the underlying dielectric layer surface 107 and forming trenches or openings 197 stopping on the surface of the bottom electrode surface 128. In an embodiment, the lithographic patterning step can include forming a photoresist (not shown) atop surfaces of the spacers 191 and cap layer 177, exposing the photoresist to a desired pattern of radiation and then developing the exposed photoresist utilizing a conventional resist developer. The pattern within the photoresist is then transferred through the portion of the cap layer 177 and underlying projection liner 175 and heater metal structure 145 and stopping on the surface of the bottom electrodes. This further etching step for etching through and removing the portions of the cap layer 177, projection liner 175 and heater metal structure 145 between the spacers 191 is selective to the underlying co-planar bottom electrode surface 128 and/or dielectric material layer material surfaces 107 resulting in the structure 240 shown in FIGS. 1I-1, 1I-2.

FIG. 1J-1 shows a further view taken along an X-X cross-section of the formed intermediate PCM cell structure 200 of the layout depicted in FIG. 1E, the further view showing a resulting structure 250 formed after further processes to deposit and etch back a protective spacer on sides of the heater structure 145. That is, mask patterning and CVD, PVD, or ALD processes are performed to deposit a protective spacer material layer in the cuts 196 and openings 197 formed as a result of spacer pattern transfer etching to cut the heater in the structure 240 of FIGS. 1I-1, 1I-2. Then, dry- or plasma-etching processes are performed to remove the remaining sidewall spacers 191 by etching process selective to the surface of projection liner 175.

FIG. 1J-2 shows a view taken along a Y-Y cross-section of the formed structure of FIG. 1J-1, the view showing the result of performing CVD, PVD, or ALD processes to deposit the protective spacer material layer 255 on sides of the cut heater structure 145. A further step such as a CMP is applied to the top of the projection liner to planarize the surface 258 of protective spacer material layer 255 and projection liner 175.

FIG. 1K-1 shows a further view taken along an X-X cross-section of the formed intermediate PCM cell structure 200 of the layout depicted in FIG. 1E, the further view showing a resulting structure 300 formed after further processes to deposit the phase change material of the PCM cell. As shown in FIG. 1K-1, in one or more embodiments, CVD, PVD, or ALD processes can be used to first deposit a phase change material layer 302. The deposited phase change material can include, but is not limited to glass chalcogenides such as, for example, germanium-antimony-tellurium Ge₂Sb₂Te₅ (GST), SbTe, and In₂Se₃. Further deposition processes are performed to provide a further metal nitride top electrode layer 304 on top of the GST layer 302. In an embodiment, top electrode is composed of a metal or metal alloy material such as TaN, Ta, TiN, W, e.g., formed by CVD processes. Further, the method includes depositing a hardmask layer 306 upon the top electrode layer 304. In response to these deposition processes, one or more phase change memory (PCM) cells can be formed. A thickness of formed PCM cell layers can range from between 3 nm-800 nm. FIG. 1K-2 shows a view taken along a Y-Y cross-section of the formed structure of FIG. 1K-1.

FIG. 1L-1 shows a further view taken along an X-X cross-section of the formed intermediate PCM cell structure 200 of the layout depicted in FIG. 1E, the further view showing a resulting structure 320 formed after further processes to pattern a mask and etch the structure 300 of FIG. 1K-1 to physically separate the PCM cell layers 302, 304, 306 into two respective PCM cells. The process includes forming a trench 350 having a width dimension corresponding to a desired dimension of the respective PCM cell to be formed. The trench is etched to expose a top surface 375 of the underlying interlevel dielectric fill layer 165. In an embodiment, one or more etching processes are performed selective to the interlevel dielectric fill layer 165 to form a trench 350 by removing a portion of the PCM layers 302, 304, 306 and remove a corresponding portion of the underlying projection liner layer 175. The formed trench functions to separate and form respective PCM cell structures 375A, 375B that connect to corresponding sidewall heater structures 145A, 145B that connect to respective adjacent bottom electrodes, e.g., electrodes 108A, 108B.

FIG. 1L-2 shows a view taken along a Y-Y cross-section of the formed structure of FIG. 1L-1. As shown, as a result of the etching of the structure 300 of FIG. 1K-1, the respective edges of the stack including the GST layer 302, top electrode layer 304, e.g. TiN, W, TaN, Ru, a-C+metal, GST+metal, Co, etc., and hardmask layer 306 are recessed to form a cell of a desired width dimension.

FIG. 1M-1 shows a further view taken along an X-X cross-section of the final PCM cell structure according to the layout depicted in FIG. 1E, the further view showing a resulting structure 380 formed after further processes to pattern and deposit an encapsulation dielectric material 392 such as SiN and an interlevel dielectric layer 390, e.g., of low-k dielectric (ILD), e.g., Tetraethyl orthosilicate (TEOS) material to encapsulate each PCM cell structure 375A, 375B and to finish by forming respective top metal electrode contacts 395A, 395B that connect to a respective top electrode layer 304 of each respective PCM cell structure 375A, 375B.

FIG. 1M-2 shows a view taken along a Y-Y cross-section of the formed structure of FIG. 1M-1. In the embodiment depicted in FIG. 1M-2, there is a single PCM cell having a top electrode layer 304 connected with a single top electrode contact 395 and one GST layer connected with two connecting sidewall metal heaters, e.g., sidewall metal heaters 145B, 145C corresponding to connected bottom electrodes 108B, 108C. In such a configuration, a circuit can be controlled to only turn on one heater at a time for conducting current to a common GST layer. It is contemplated that a single bottom electrode and one sidewall metal heater can be aligned with the GST layer of a single PCM cell.

FIG. 2 depicts a three-dimensional view of the resulting PCM cell having self-aligned projection liner. The three-dimensional view provides a final PCM cell structure 400 electrically connected to a bottom electrode 408 by a sidewall heater electrode formed as a result of side wall electrode processes and having an added projection liner segment 405 functioning as a parallel resistor that bypasses current around the amorphous volume of the GST layer of the PCM cell. In the final PCM cell structure 400 of FIG. 2, the sidewall metal heater segment 410 has the connecting resistive projection liner segment 405 with a width that is self-aligned to the width of the heater electrode. That is, the projection liner is formed such that by the patterning, the width of the projection liner is etched at the same time as the sidewall heater metal layer is etched, thus forming a self-aligned projection liner. In the embodiment depicted in FIG. 2, a length of the resistive projection liner segment 410 is substantially equal to a length of said PCM memory cell bottom layer.

FIG. 3A depicts a view of the resulting PCM cell 450 having an added self-aligned projection liner structure 455 formed to extend along the entire length L of the bottom layer 452 of the PCM cell and electrically connected to and self-aligned with the heater electrode 460. FIG. 3B depicts a view of the resulting PCM cell 475 having self-aligned projection liner 456 formed to extend for a length less than (<) the entire length L of the bottom layer 452 PCM cell. As shown, the structure 475 of FIG. 3B includes self-aligned projection liner 456 portion extending from the location where the heater electrode 460 connects to the projection liner to an edge of the bottom layer 452 PCM cell. In an embodiment, the self-aligned projection liner 456 portion extends for a length of approximately one-half the length of the bottom layer 452 to an edge of the bottom PCM cell layer.

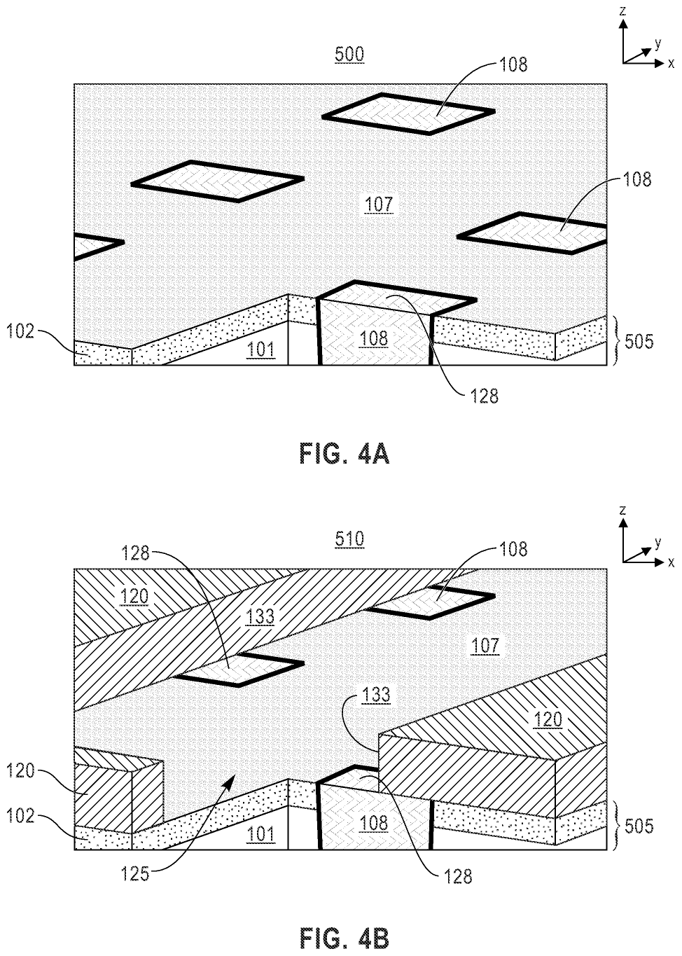

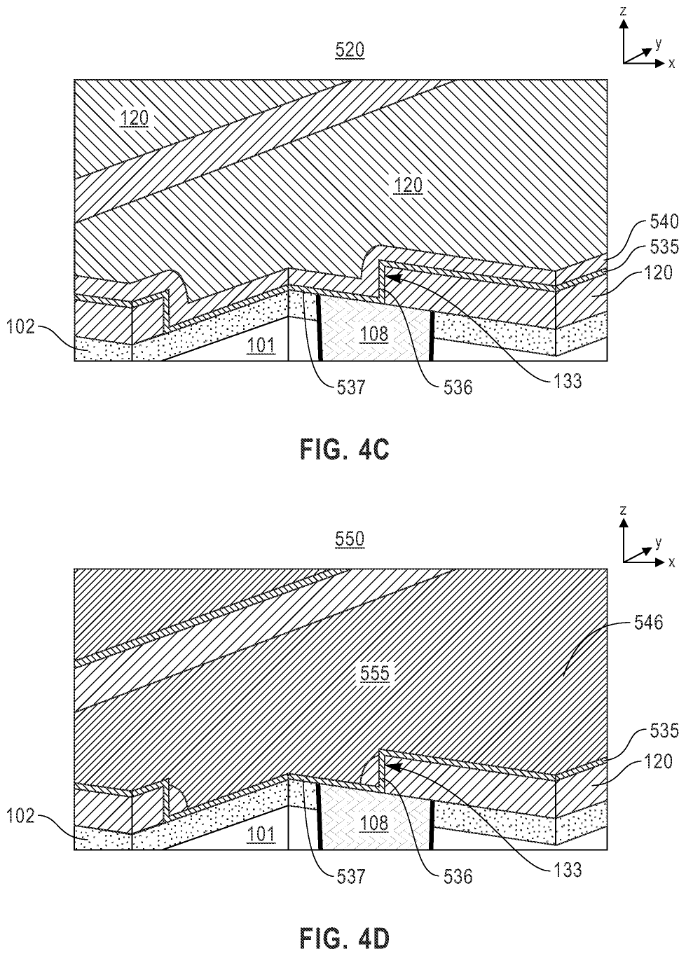

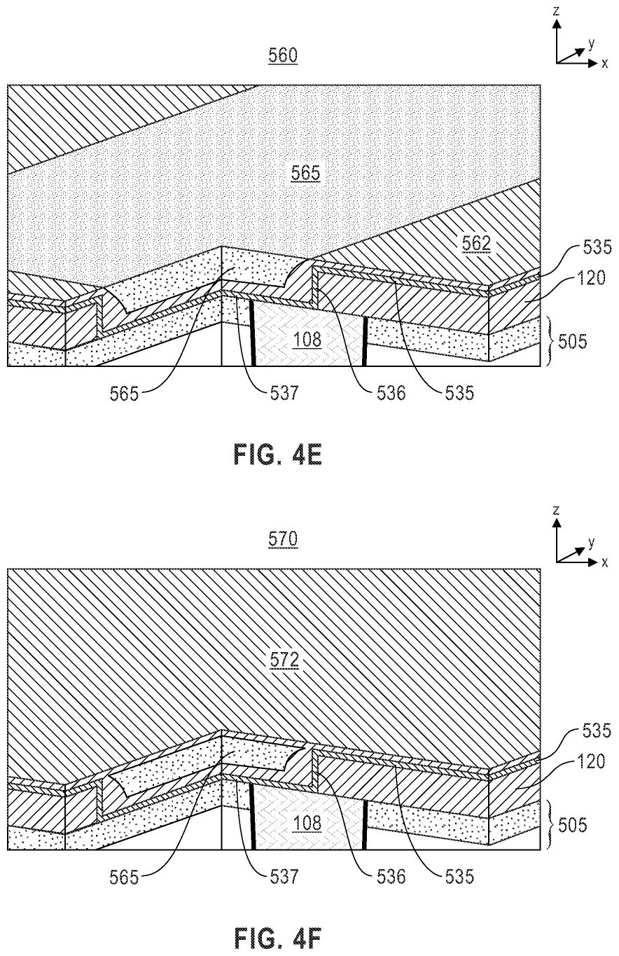

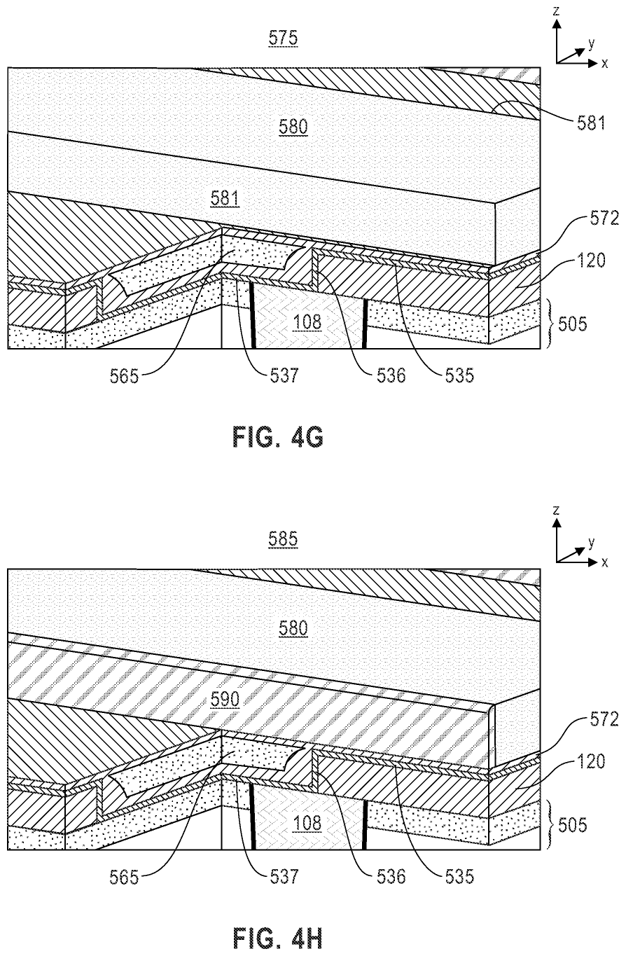

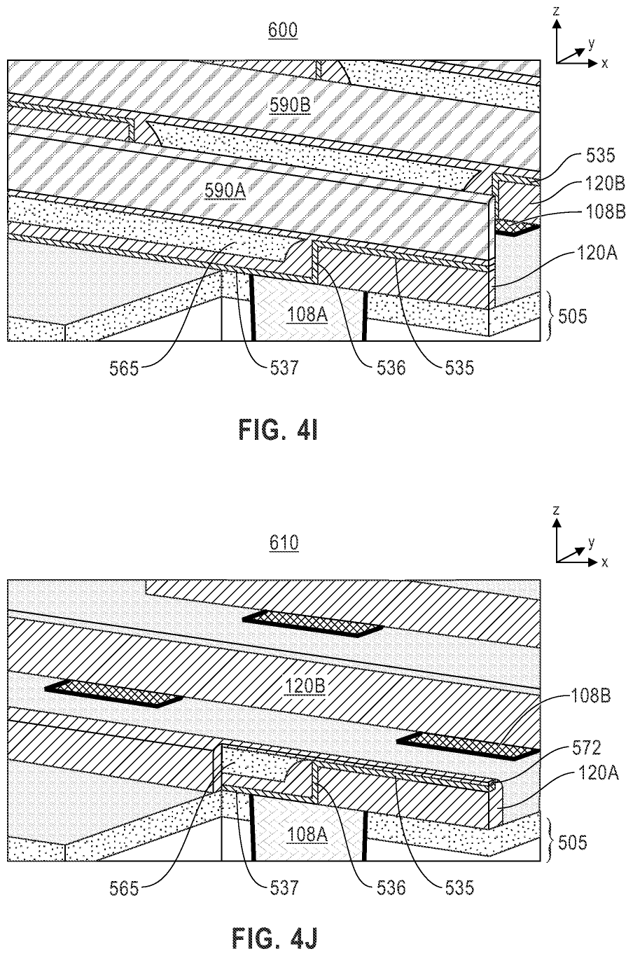

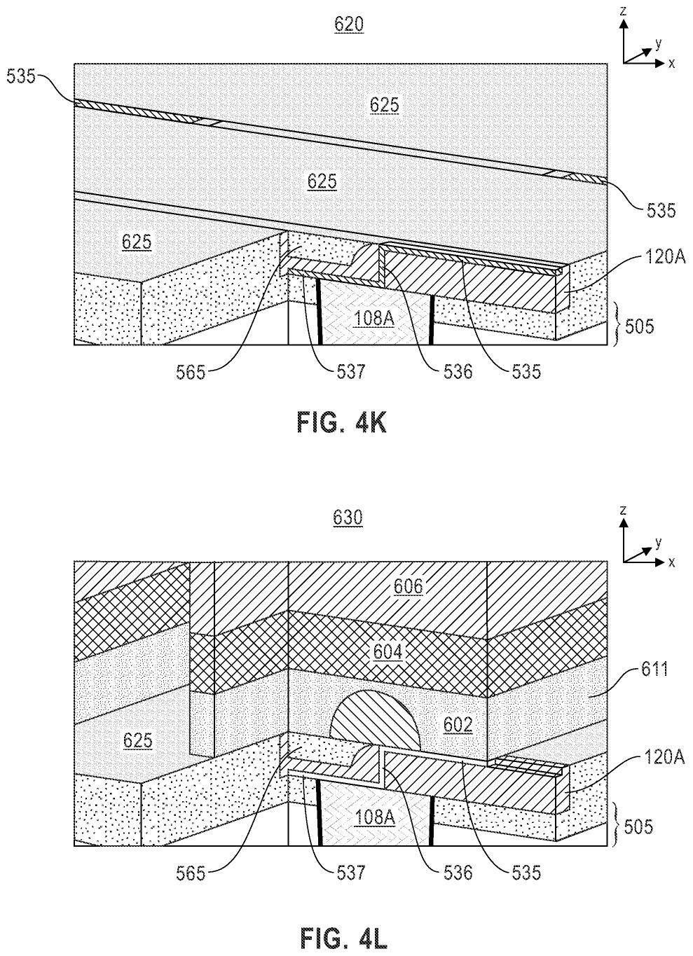

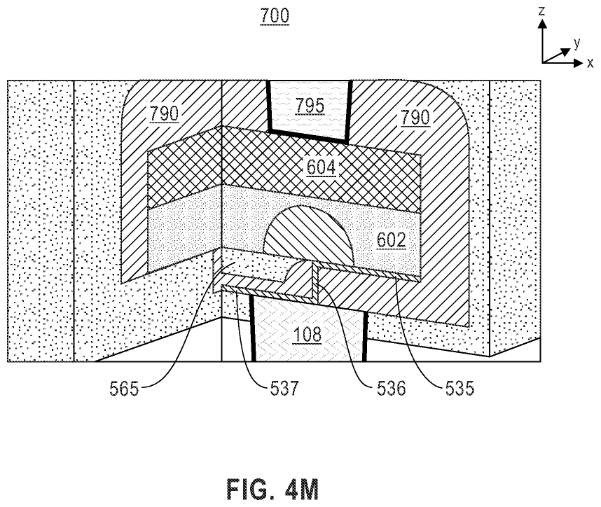

FIGS. 4A-4M illustrate three-dimensional cross-sectional views depicting a sequence of semiconductor manufacturing MOL and BEOL process steps of a self-aligned projection liner integration scheme that results in semiconductor PCM structures that include an added self-aligned projection liner according to a second embodiment.

FIG. 4A is a 3-dimensional cross sectional view of an exemplary structure 500 that can be used as the basis for forming a PCM cell structure using a self-aligned projection liner integration scheme in one embodiment. Initial structure 500 is identical to the structure 100 of FIG. 1A formed of MOL or BEOL semiconductor manufacturing processes for fabricating conductive wiring, contacts, insulating material layers, metal levels, etc. that can interconnect already formed individual devices such as transistors, capacitors, resistors, etc. (not shown). The starting structure 500 can a stack of one or more dielectric layers 105 including, from bottom to top first level dielectric layers including a first dielectric layer 101, e.g., materials including but not limited to SiN, SiON, SiOCN, and a second interlevel dielectric level layer or dielectric cap layer 102. The second insulator layer 102 can be composed of dielectric materials, such as silicon dioxide, silicon nitride, silicon carbide nitride, or other types of low-k dielectric materials. The term “low-k” as used throughout the present application denotes a dielectric material that has a dielectric constant of less than 4.0; all dielectric constants are measured under vacuum (unless otherwise stated herein). In an embodiment, interlevel dielectric layer 102 can be tetraethoxysilane (TEOS) or fluorinated tetraethyl orthosilicate (FT EOS) material. Such a dielectric film can be deposited using plasma enhanced physical vapor deposition (PECVD).

Formed within dielectric layer stack 505 are a plurality of bottom electrodes 108 for eventual connection to a PCM cell, each bottom electrode 108 having a surface 128 co-planar with a top surface 107 of the interlevel dielectric layer 102. The metal bottom electrodes 108 can be composed of metal such as graphite, copper, tungsten, Pt, Ru, Ni, or other metal or metal alloy suitable for forming an electrode that connects to the other conductors/devices (not shown). The bottom electrode metal material structures 108 can be deposited by, but not limited to, atomic layer deposition (ALD), chemical vapor deposition (CVD), or physical vapor deposition (PVD) processes.

FIG. 4B is a 3-dimensional cross sectional view of an exemplary structure 510 resulting from performing further material deposition, photolithographic mask patterning and etching processes to form respective dielectric heater structures 120 on top of the surface 107 that cover a portion of a respective bottom electrode surface 128. As shown in FIG. 4A, each structure 120A overlaps with and covers approximately one-half a surface of a respective electrode top surface 128 and leaves approximately one-half of the surface 128 of each bottom electrode 108 exposed in one embodiment. In one embodiment, the structure 510 in FIG. 1B results from a deposition of a dielectric heater material layer (not shown) and, using photolithographic mask patterning processes and plasma-etching, dry-etching or ion beam etching or laser ablation processes to result in the forming of an opening 125 so that remaining dielectric heater layer portions 120A, 120B cover a portion of each electrode surface 128 on top the layer stack 505. In an embodiment, a reactive-ion etching (RIE) is used to form the opening resulting in the formed dielectric heater layer portions 120 each portion having inner sidewalls 133. The deposited dielectric heater layer portions 120 can be composed of dielectric materials, such as silicon nitride (SiN), silicon carbide nitride, or other types of dielectric heater materials, e.g., TEOS, SiOC, SiOCN.

FIG. 4C is a 3-dimensional cross sectional view of an exemplary structure 520 resulting from performing further processing steps of depositing a heater metal layer 535 and an overlying protective spacer layer 540 on top the deposited metal heater layer 535. As shown, the heater metal 535 is deposited to cover the top surface of the deposited dielectric heater layer portions 120A, 120B and include sidewall portion 536 conforming to the inner sidewalls 133 of dielectric heater layer portions and includes a portion 537 covering the top surface 107 of the exposed ILD layer 102 including covering for electrical connection with each of the remaining exposed surfaces of each bottom electrode. The metal heater layer 535 can be deposited to thickness ranging between 6 nm-8 nm however heater metal layer thickness can range from between 2 nm-10 nm. The deposited protective spacer material layer 540 overlies heater metal layer 535 and is deposited to a thickness ranging anywhere from between 10 nm-30 nm. Both layers 535, 540 can be deposited by, but not limited to, atomic layer deposition (ALD), chemical vapor deposition (CVD), or physical vapor deposition (PVD) processes. Metal heater materials can include, but are not limited to: W, Ti, TiN, TaN, Ru, OTS or other metals or metal nitrides. The protective space material can include, but is not limited to an oxide or nitride insulator, such as silicon oxide, silicon nitride, or silicon-oxynitride, etc. Other protective spacer material can include Al₂O₃, AlN, SiOCN, Ge—Se based ovonic threshold switching such as Sb and N doping of Se-rich Ge—Se.

FIG. 4D is a 3-dimensional cross sectional view of an exemplary structure 550 resulting from performing further RIE or plasma-etching process etch back spacer material layer 540 but avoiding etching back of the heater metal material layer 535 in the structure 520 of FIG. 4C. FIG. 4D depicts the remaining heater metal material layer 535 located along the sidewall edges 133 of the dielectric heater layer portions 120A, 120B. The result of the etching process is to form an opening 555 to expose the surface 546 of metal heater layer 535.

FIG. 4E is a 3-dimensional cross sectional view of an exemplary structure 560 resulting from further depositing a protective cap layer 562 and fill in dielectric material 565 within the opening 155 and on all exposed surfaces of the structure 550 of FIG. 4D. The protective cap layer 562 can be of a dielectric material such as a nitride dielectric which consists of Si, C, H, and N, e.g., SiN, SiCHN, or combinations thereof and can be deposited by atomic layer deposition, chemical vapor deposition, or physical vapor deposition processes. The fill-in dielectric material layer 565 can include a Tetraethyl orthosilicate (TEOS) dielectric material layer 165 using CVD, PECVD or PVD processes.

FIG. 4F is a 3-dimensional cross sectional view of an exemplary structure 570 resulting from performing further processing steps of depositing a hard mask layer 572 an the structure 560 of FIG. 4E. Hard mask material can include a metal nitride such as SiN or other materials such as Al₂O₃, AlN, HfO₂, TiN, a-C. Afterwards, the structure 570 of FIG. 4F can undergo chemical mechanical polishing (CMP) processes to planarize a top surface.

FIG. 4G is a 3-dimensional cross sectional view of an exemplary structure 575 resulting from performing further processing steps of deposition, photolithographic mask patterning and etching processes to form a mandrel structure 580. In an embodiment, the top surface of the hard mask layer 572 of the structure 570 is patterned with a mask and a mandrel material is deposited and the mask removed to form a mandrel structure 580 oriented in a direction transverse to the orientation of the heater metal layer 535 on the top surface of the dielectric heater 120A structure of FIG. 4D. The use of conventional semiconductor photolithographic masking and etching techniques result in a mandrel material structure 580 of a width defining two edges 581, each edge 581 overlapping a respective adjacent bottom electrode 108 of a transverse orientation relative to the orientation of the heater metal and dielectric layer. Deposited mandrel material structure 580 can be of an amorphous silicon (a-Si) material or other like mandrel dielectric materials such as BARC (bottom anti-reflection coating), OPL (outer plexiform layer), SiO₂, SiOC, AlN, Al₂O₃, TiN, TaN.

FIG. 4H shows a further 3-dimensional cross sectional view of an exemplary structure 585 resulting from performing further processing steps of further depositing a spacer material layer on the exposed top surfaces of the structure 575 of FIG. 4G and after further processing to pattern and etch-back the deposited spacer material layer to form respective spacers 590 on each side edge 581 of the patterned mandrel 580. In an embodiment, a dry or RIE etch process is performed to remove those portions of the deposited spacer material layer (not shown) above the mandrel structure 580 while leaving thin sidewall spacer portions 590 on each side of the mandrel material layer 580. Each respective thin sidewall spacer portion 590 are in vertical alignment with a respective bottom electrode, e.g., electrode 108. Sidewall spacers 590 can be of a material such as AlN, Ti₂O₃ or other materials such as SiN, Al₂O₃, HfO2, TiN, SiOCN.

FIG. 4I shows a further 3-dimensional cross sectional view of an exemplary structure 600 resulting from performing further processing steps to remove (pull) the mandrel structure 580. That is, mask patterning and dry-etching (e.g., RIE) or plasma-etching processes are performed to remove the mandrel structure 580 from the surface of mask layer 572 between sidewall spacers 590 while leaving the sidewall spacers 590A, 590B in tact. Each remaining respective thin sidewall spacer portion 590A, 590B are in vertical alignment with a respective bottom electrode, e.g., electrode 108A, 108B, of an array.

FIG. 4J shows a further 3-dimensional cross sectional view of an exemplary structure 610 resulting from performing further processing steps to transfer the spacer pattern defined by remaining vertical spacers 590A, 590B by etching the structure 600 of FIG. 4I to cut portions of the heater layer 535 according to the pattern defined by the spacers. That is, mask patterning and dry- or plasma-etching (e.g., RIE) processes are performed to remove those portions of the hard mask layer 572, the dielectric heater layer 120 and portions of heater metal structure 535 between the spacers 590A, 590B, etc. The etching results in each electrode, e.g., electrodes 108A, 108B, having an overlying dielectric heater layer 120A, 120B and a respective metal heater layer 535, including metal heater sidewall portion 536 and overlying metal heater portion 537 on the surface of bottom electrode. Exemplary structure 610 of FIG. 4J shows a further result of performing further etching processes to remove each of the sidewall spacers 590A, 590B selective to the surface of dielectric heater layers 120A, 120B, etc.

FIG. 4K shows a further 3-dimensional cross sectional view of an exemplary structure 620 resulting from performing further processing steps to deposit and etch back a protective spacer layer 625 on each side of the metal heater 535 and corresponding dielectric heater structure, e.g., dielectric heater structure 120A. Exemplary structure 620 of FIG. 3K shows a further result of performing further CMP processes to planarize a top surface of the protective spacer layers 625 and metal heater liner layer 535.

FIG. 4L shows a further 3-dimensional cross sectional view of an exemplary structure 630 resulting from performing further mask patterning, deposition and etching processing steps to deposit the phase change material layer, top electrode layer, and hardmask layer used to form the PCM cell 700 shown in FIG. 4M. As shown in FIG. 4L, in one or more embodiments, patterning, CVD, PVD, or ALD deposition and etching processes can be used to form a phase change material layer 602. The deposited phase change material can include, but is not limited to glass chalcogenides such as, for example, germanium-antimony-tellurium Ge₂Sb₂Te₅ (GST), SbTe, and In₂Se₃. Further patterning, deposition and etching processes are performed to form a further metal nitride top electrode layer 604 on top of the GST layer 602. In an embodiment, top electrode is composed of a metal or metal alloy material such as TaN, Ta, TiN, W, e.g., formed by CVD processes. Further, the method includes patterning, depositing and etching a hardmask layer 606 upon the top electrode layer 604. In response to these deposition processes, one or more phase change memory (PCM) cells are formed. Further, in forming the PCM cell structure 630 shown in FIG. 4L, after further photolithographic mask patterning, the PCM cell layers is etched down to the dielectric heater level. This processing results in a PCM cell having an underlying metal heater 535 that functions as a projection liner segment that contacts the overlying bottom GST layer of the PCM cell. The metal heater layer 535 includes a sidewall metal heater portion 536 and further extends from the sidewall portion 536 beneath the GST layer 602 to the edge 611 of the PCM cell.

FIG. 4M shows a resulting three-dimensional view of the final PCM cell structure 700 formed on bottom electrode 108 having a sidewall metal heater 536 including a metal heater segment 535 functioning as a parallel resistor to bypass current around the amorphous volume of the GST layer 602 of the PCM cell. In the final PCM cell structure 700 of FIG. 4M, the sidewall metal heater segment 536 has the connecting metal heater portion 535 functioning as a resistive projection liner segment with a width that is self-aligned to the width of the heater element 536. That is, the metal heater portion 535 is formed such that by the mandrel spacer patterning processes, the width of the metal heater portion 535 is etched at the same time as the spacer patter transfer etching is performed as shown in FIG. 4J, thus forming a self-aligned metal heater segment. In the embodiment depicted in FIG. 4M, a length of the metal heater segment 535 is substantially equal to one-half the length of said PCM memory cell bottom GST layer. The resulting PCM cell structure 700 shown in the view of FIG. 4M further depicts the result of further processes to pattern and deposit an encapsulation dielectric material 790 such as an interlevel dielectric layer of low-k dielectric (ILD), e.g., Tetraethyl orthosilicate (TEOS) material and to finish by forming a respective top metal electrode contact 795 to connect to a top electrode layer 604 of the PCM cell structure.

The processes of the present disclosure can be used for development of a 3D cross-point based resistive memory technology. In an embodiment, the methods can be used to provide a projection liner that can be significantly narrower than with the case of a non-self-aligned case, thus reducing contact with the PCM memory cell which can result in a higher dynamic range. As liner typically drops dynamic range significantly, the method and structures of the present disclosure could enable larger switching window with drift mitigation. A lower drift migration coupled with large switching window is a key enabler for analog AI applications.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A memory device comprising:
a bottom metal electrode having a top surface;
a memory cell disposed above the bottom electrode, said memory cell having a bottom layer comprising a phase change material;
a resistive projection liner element connecting to the bottom layer of said memory cell; and
a metal heater element connecting the top surface of said bottom electrode to said resistive projection liner element, the resistive projection liner element being self-aligned to the metal heater element to reduce an area of contact to said memory cell.

2. The memory device as claimed in claim 1 wherein a width dimension of said resistive projection liner conductor is substantially equal to a width dimension of said metal heater element.

3. The memory device as claimed in claim 2 wherein a length of said resistive projection liner conductor is substantially equal to a length of said memory cell bottom layer.

4. The memory device as claimed in claim 2 wherein a length of said resistive projection liner conductor is less than the length of said memory cell bottom layer.

5. The memory device as claimed in claim 2, further comprising:
a dielectric material heater structure having a sidewall edge extending in a first orientation and in alignment with a surface of said bottom metal electrode, wherein the metal heater element includes a side wall electrode portion formed on said sidewall edge the dielectric material heater structure and includes a bottom portion connecting the top surface of the bottom electrode.

6. The memory device as claimed in claim 2 wherein the bottom electrode is formed in a dielectric material layer of a semiconductor wafer.

7. The memory device as claimed in claim 2 further comprising: a plurality of bottom metal electrodes each having a top surface, wherein a single memory cell is disposed above and electrically connected to two bottom electrodes via respective side wall metal heater elements.

8. A semiconductor structure comprising:
a bottom metal electrodes having a top surface;
a memory cell disposed above the bottom electrode, said memory cell having a bottom layer comprising a phase change material;
a metal heater element connecting the top surface of said bottom electrode to a bottom surface of the bottom layer of the memory cell, said metal heater element having a substantially vertical extending sidewall liner portion and a horizontal liner portion extending to an edge of the bottom layer, said horizontal liner portion extending for a length less than an entire length of the bottom layer of the memory cell to reduce an area of contact to said memory cell.

9. The semiconductor structure as claimed in claim 8 wherein a width dimension of said vertical extending sidewall liner portion and a horizontal liner portion of the metal heater element is substantially equal.

10. The memory device as claimed in claim 9, further comprising:
a dielectric material heater structure having a sidewall edge extending in a first orientation and in alignment with a surface of said bottom metal electrode, wherein the vertical extending sidewall liner portion is formed on said sidewall edge the dielectric material heater structure and includes a bottom portion connecting the top surface of the bottom electrode.

11. A method of fabricating a semiconductor memory device comprising:
depositing, on a semiconductor structure having one or more formed bottom metal electrodes, one or more first heater dielectric material layer structures, each first heater dielectric material structure having a sidewall edge extending in a first orientation and in alignment with a surface of each of said one or more formed bottom metal electrodes;
forming a metal heater layer having a portion extending vertically along the sidewall edge of each said deposited first (heater) dielectric material structure and a bottom portion electrically connecting to the surface each said one or more formed bottom metal electrodes;
depositing a further dielectric material layer to fill openings at a surface of said semiconductor structure defined between sidewall edges of the one or more first heater dielectric material layer structures and planarizing a top surface thereof;
depositing a projection liner layer on said planarized top surface;
forming a pattern of vertically extending spacer material structures on the projection liner layer, each said formed vertically extending spacer material structure extending in a second orientation transverse to said first orientation and overlapping said vertically extending over the sidewall portion of said metal heater layer;
transferring a pattern defined by the vertically extending spacer material layers to the surface of each of a plurality of one or more formed bottom electrodes by etching the projection liner layer and metal heater layer to self-align a width of a remaining projection liner layer portion to a width of the cut vertically extending sidewall metal heater layer portion in the second orientation above each bottom electrode.

12. The method as claimed in claim 11, further comprising:
after etching the projection liner layer and self-aligned metal heater layer, depositing a protective spacer material on both sides of the cut metal heater layer; and
etching back said protective spacer material on each said both sides of the cut metal heater layer to define a top surface coplanar with a top surface of said remaining portions of said projection liner.

13. The method as claimed in claim 12, further comprising:
forming, on the coplanar top surface, a respective phase change memory cell on top a corresponding remaining portion of a respective projection liner and a connecting sidewall edge metal heater portion.

14. The method as claimed in claim 11, wherein said forming a metal heater layer having a portion extending vertically along a sidewall layer comprises:
depositing a metal heater material upon said one or more first heater dielectric material layer structures and conforming to the sidewall edge extending in a first orientation; and
depositing a spacer material on top said deposited metal heater material layer;
etching back portions of said spacer and metal heater layer to result in forming said vertically extending sidewall portion.

15. The method as claimed in claim 11, further comprising:
prior to depositing a projection liner layer on said planarized top surface, performing a chemical mechanical polishing to tailor a height of said metal heater sidewall to a desired height.

16. The method as claimed in claim 11, wherein said forming a pattern of vertically extending spacer material layers in said second orientation comprises:
patterning and depositing on the top surface of said resulting structure a dielectric material mandrel having at least one sidewall edge extending in a second orientation transverse to said first orientation and overlapping said vertically extending heater metal layer portion;
forming a vertically extending spacer at each the at least one sidewall edge of said mandrel; and
removing said dielectric material mandrel while retaining each formed vertically extending spacer at each sidewall edge of said mandrel.

17. The method as claimed in claim 11, wherein said depositing a projection liner layer on said planarized top surface is an optional step, said method alternatively comprising;
forming a metal heater layer having a further top portion connecting a portion extending vertically along the sidewall edge of each said deposited first heater dielectric material structure and the top portion extending to cover a surface of the first heater dielectric material structure for electrical connection to a bottom surface of a formed PMC memory cell.

18. The method as claimed in claim 17 wherein said method alternately comprises further:
forming a hardmask layer on a top surface of the formed top portion of the deposited metal heater layer; and
forming a pattern of vertically extending spacer material structures on the hardmask layer, each said formed vertically extending spacer material structure extending in a second orientation transverse to said first orientation and overlapping said vertically extending over the sidewall portion of said metal heater layer.

19. The method as claimed in claim 18 wherein said method alternately comprises further:
transferring a pattern defined by the vertically extending spacer material layers to the surface of each of a plurality of one or more formed bottom electrodes by etching the hardmask layer and a portion of said metal heater layer extending in said second orientation to result in a remaining top portion of said metal heater layer self-aligned to a width of the cut vertically extending sidewall metal heater layer portion above each bottom electrode

20. The method as claimed in claim 18 wherein said method alternately comprises further:
after etching the hardmask layer and a portion of said metal heater layer extending in said second orientation, depositing a protective spacer material on both sides of the cut metal heater layer; and
etching back said protective spacer material on each said both sides of the cut metal heater layer to define a top surface coplanar with a top surface of said remaining self-aligned top portion of said metal heater layer.
